(19) United States
(12) Patent Application Publication
(10) Pub. No.: US 2015/0317942 A1
(43) Pub. Date: Nov. 5, 2015

(54) DISPLAY DEVICE

(71) Applicant: SHENZHEN CHINA STAR OPTOELECTRONICS TECHNOLOGY CO., LTD., Shenzen (CN)

(72) Inventors: Dongsheng GUO, Shenzhen (CN); Jianyong FU, Shenzhen (CN)

(21) Appl. No.: 14/233,157

(22) PCT Filed: Nov. 14, 2013
(86) PCT No.: PCT/CN2013/087140

§ 371 Date: Jan. 16, 2014

(30) Foreign Application Priority Data
Oct. 23, 2013 (CN) 201310504054.7

(51) Int. Cl. G09G 3/36; H02M 3/04; H05K 1/02

(52) U.S. Cl. CPC G09G 3/3696; H05K 1/0216; H05K 1/0286; H02M 3/04; G09G 2330/06; G09G 2330/02

(57) ABSTRACT

A display device capable of reducing electromagnetic interference includes a display panel which has a source driver and a gate driver; a connector; a DC-DC converter; a first trace for connecting the connector and the DC-DC converter; and a second trace for connecting the DC-DC converter and the source driver, wherein the DC-DC converter is disposed near the gate d river, and a length of the first trace is longer than a length of the second trace, so that it minimizes the path of the DC-DC converter outputting current, and reduces the generation of electromagnetic interference.

### FIELD OF THE INVENTION

The present invention relates to a display device, of which electromagnetic interference is reduced.

### BACKGROUND OF THE INVENTION

In general, the operation process of driving a display device comprises: a voltage outputted by a power source circuit passes through a DC-DC converter in a printed circuit board assembly (PCBA), so as to provide various driving voltages which a display panel needs. When the display device is driven, the electronic components in the display device will generate electromagnetic waves which cause the electronic components to produce electromagnetic interference (EMI), and may even affect the image display quality. In general, a high-current will produce greater electromagnetic interference.

Please refer to FIG. 1. FIG. 1 shows a display device 10 of prior art, which comprises a display panel 50 having a source driver series 30 deployed in a first direction, and a gate driver series 40 deployed in a second direction, and a printed circuit board 20 deployed on the side in the first direction of the display panel 50. The printed circuit board 20 is electrically connected to the source driver series 30. A connector 21 is disposed on a side of the printed circuit board 20 opposite to the side where the source driver series 30 is connected. The connector 21 is used for connecting a power circuit 25, so as to receive a voltage generated by the power circuit 25. The printed circuit board 20 is provided with a plurality of elements, including the connector 21 and a DC-DC converter 22. Therefore, the structure of printed circuit board 20 is formed with a certain width (the distance from the side of the connector 21 to the side of the source driver series 30). In the prior art, considering that the high-current would cause interference to other electric circuits, and that the outputting current from the connector 21 is greater than the outputting current from the DC-DC converter 22, the DC-DC converter 22 is disposed near the connector 21. That is, a length of a first trace 23 connecting the connector 21 and the DC-DC converter 22 is shorter than a length of a second trace 24 connecting the source driver 30 and the DC-DC converter 22. However, in practice, the inventor tested and found the EMI generated by the second trace 24 is greater than the EMI generated by the first trace 23. That is, the EMI is derived from a path between an output terminal of the DC-DC converter 22 and the source drivers. In order to overcome the deficiencies of the prior art, the present invention provides a display device capable of improving electromagnetic interference.

### SUMMARY OF THE INVENTION

The object of the present invention is to dispose a DC-DC converter close to the gate drivers by changing the layout design of a printed circuit board, so that it minimizes the path of current and voltage and reduces the generation of electromagnetic interference.

To achieve the above object, the present invention provides a display device, the display device includes: a display panel having a source driver deployed in the first direction and a gate driver deployed in the second direction, wherein the source driver and the gate driver are used for driving the display panel; a connector for connecting an external power source to receiving a voltage therefrom; a DC-DC converter provided close to the gate driver and electrically connected to the source driver, the gate driver, and the connector for receiving the voltage from the connector and converting the voltage into a driving voltage to be applied to the display panel; a first trace for connecting the connector and the DC-DC converter; and a second trace for connecting the DC-DC converter and the source driver, wherein a length of the first trace is longer than a length of the second trace.

In the above-described display device, the DC-DC converter includes a pulse width modulation circuit and a charge pump, and the pulse width modulation circuit is electrically connected to the charge pump.

In the above-described display device, the DC-DC converter is disposed on a printed circuit board.

In the above-described display device, the trace of the power circuit is covered with a shielding material

In the above-described display device, the shielding material is copper foil.

In the above-described display device, the voltage outputted from the connector to the DC-DC converter is 12 volts.

A printed circuit board for a display device, the display device includes a display panel having a source driver deployed in the first direction and a gate driver deployed in the second direction, wherein the source driver and the gate driver are used for driving the display panel, the printed circuit board comprising: a connector for connecting an external power source to receiving a voltage therefrom; a DC-DC converter for transmitting the voltage to the source driver and the gate driver; a first trace for connecting the connector and the DC-DC converter; and a second trace for connecting the DC-DC converter and the source driver, wherein a length of the first trace is longer than a length of the second trace.

In the above-described printed circuit board, the DC-DC converter includes a pulse width modulation circuit and a charge pump, and the pulse width modulation circuit is electrically connected to the charge pump.

In the above-described printed circuit board, the first trace is covered with a shielding material.

In the above-described printed circuit board, the shielding material is copper foil.

The object of the present invention is to provide a display device capable of improving the electromagnetic interference. In the prior art, the DC-DC converter is disposed near the input terminal of the power source in the layout design of the printed circuit board, but the DC-DC converter of the present invention is disposed near the source driver, so that it minimizes the path of the current and voltage and reduces the generation of electromagnetic interference.

In order to make the present invention more clear, preferred embodiments, and the drawings thereof, are described in detail below.

### BRIEF DESCRIPTION OF THE DRAWINGS

FIG. 1 shows a schematic view of a display device of the prior art;

FIG. 2 illustrates a display device according to an embodiment of the present invention;

FIG. 3 shows a block diagram of the DC-DC converter;

FIG. 4 illustrates a cutaway view of the trace of the power circuit according to an embodiment of the present invention.

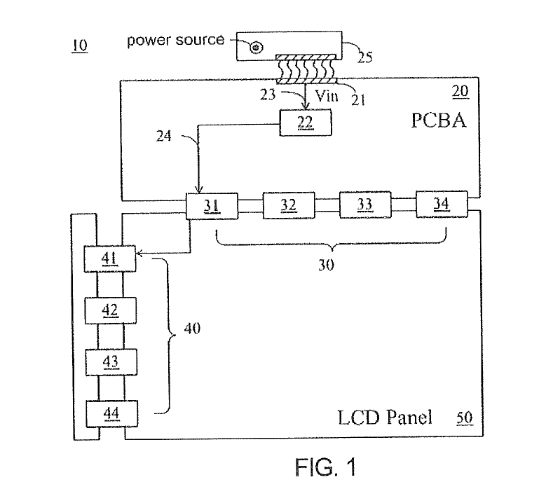

### DETAILED DESCRIPTION OF THE INVENTION

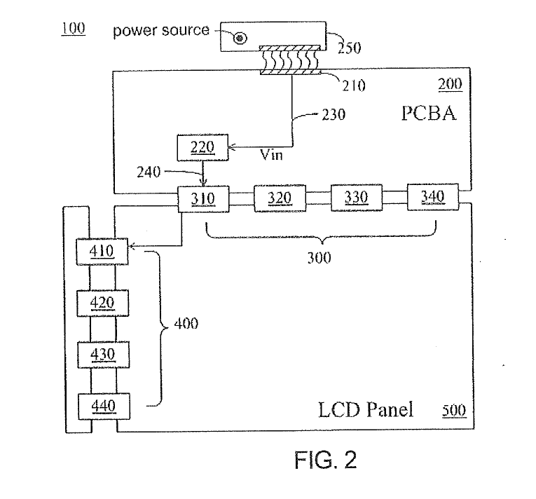

FIG. 2 illustrates a display device 100 according to an embodiment of the present invention. The display device 100 includes a display panel 500 which has a gate driver series 400 deployed in the first direction and a source driver series 300 deployed in a second direction. The gate driver series 400 includes lots of gate drivers 410, 420, 430, and 440, and the source driver series 300 includes lots of source drivers 310, 320, 330, and 340. Although the illustrated embodiment is shown as having four date drivers and four source drivers, it should be noted that in one embodiment other numbers of gate drivers and source drivers may be included.

Furthermore, in the present embodiment, the display device 100 includes a power circuit 250, a connector 210, a DC-DC converter 220, a first trace 230, and a second trace 240. The connector 210, the DC-DC converter 220, the first trace 230, and the second trace 240 are disposed on a side in the first direction of the display panel 500. The connector 210 is connected with the DC-DC converter 220 by the first trace 230, and the DC-DC converter 220 is connected with the source driver series 300 by the second trace 240. The connector 210 is connected with the power circuit 250 for receiving a voltage generated by the power circuit 250. Therefore, the connector 210 outputs the voltage to the DC-DC converter 220 through the first trace 230. The DC-DC converter 220 adjusts the voltage received from the power circuit 210, and outputs the voltage to a source driver 310 of the source driver series 300 through the second trace 240. The source driver 310 is electrically connected to the other source drivers 320 to 340 and the gate driver series 400, so as to provide various driving voltages which the display panel 500 needs for driving the display panel 500. The voltage of the DC-DC converter 220 transmitting to the source driver series 300 and the gate driver series 400 includes a gate high voltage (VGH), a gate low voltage (VGL), and a main voltage (VAVDD), wherein the VGH and VGL are transmitted to the gate driver series 400, and the VAVDD is transmitted to the source driver series 300.

It should be noticed that the second trace 240 is the connecting line of the DC-DC converter 220 and the source driver 310. Although the DC-DC converter 220 may transmit electric power to the other source drivers 320 to 340 and the gate driver series 400 through the source driver 310, the second trace 240 does not contain the connecting line that the source driver series 300 uses to transmit electric power to other source drivers 320 to 340 and the gate driver series 400. In the structure, the DC-DC converter 220 is closer to the side in the first direction of the display panel 500 than the connector 210. That is, the distance of between the connector 210 and the display panel 500 is greater than the distance between the DC-DC converter 220 and the side in the first direction of the display panel 500.

Furthermore, according to the above-described display device 100, if the DC-DC converter 220 is disposed near the connector 210, it will cause current voltage with a long output path, so as to generate a large amount of the electromagnetic interference. Therefore, in the above-described display device 100, the elements of DC-DC converter 220 are partially or entirely disposed near the source driver series 300. Since the source driver 310 of source driver series 300 will transmit electric power to the other source drivers 320 to 340 and the gate driver series 400 through the connecting line, a preferred embodiment of the present invention is the element of the DC-DC converter 220 partially or entirely disposed near the source driver series 300 and the gate driver series 400. That is, the DC-DC converter 220 is disposed near the intersection in the first direction and the second direction, so that it minimizes the path of the DC-DC converter 220 outputting current voltage. A length of the second trace is shorter than a length of the first trace, thereby reducing the electromagnetic interference generated by the output terminal of the DC-DC converter 220, further achieving a better display effect.

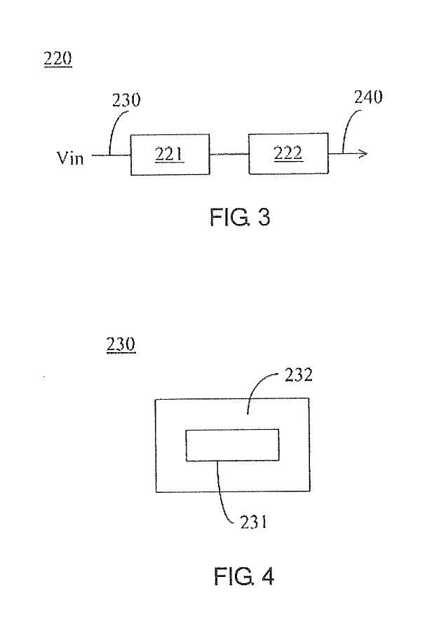

In addition, in the above-described display device 100, as shown in FIG. 3, the DC-DC converter 220 includes a pulse width modulation (PWM) circuit 221 and a charge pump 222. The pulse width modulation circuit 221 receives an input voltage (Vin) for pulse width modulation, and outputs periodic pulse signals to the charge pump 222. The voltage from the pulse width modulation circuit 221 is adjusted to a gate high voltage (VGH) and a gate low voltage (VGL) by the charge pump 222. The gate high voltage and the gate low voltage are provided to the gate driver series 400.

In the present preferred embodiment, the connector 210 and the DC-DC converter 220 of the display device 100 are disposed on a printed circuit board 200. The printed circuit board 200 is located on a side in the first direction of the display panel 500. In the present embodiment, in order to achieve that the DC-DC converter 220 be disposed near a side in the first direction of the display panel 500 the layout design of a printed circuit board just needs to be changed. Further, the DC-DC converter 220 is disposed near the intersection in the first direction and the second direction. That is, the DC-DC converter 220 is disposed near the position of the source driver series 300 and the gate driver series 400.

In the present embodiment, in order to achieve that the elements of the DC-DC converter 220 are partially or entirely disposed near the gate driver series 400 the layout design of a printed circuit board 200 just needs to be changed. For example, only the charge pump 222 of the DC-DC converter 220 is disposed near the gate driver series 400, or the pulse width modulation circuit 221 and the charge pump 222 of the DC-DC converter 220 are disposed near the gate driver series 400.

In addition, in the above-described display device 100, as shown in FIG. 4, the first trace 230 outputs a voltage from the connector 210 to the DC-DC converter 220, and the core 231 of the first trace 230 is an output voltage (12 volts) trace. The core 231 is covered with a shielding material 232 for shielding from the electromagnetic interference which comes from the neighboring electronic components or modules, wherein the shielding material may be a ground wire (GNP which is in the structure of the printed circuit board 200. More specifically, during the process of producing the printed circuit board 200, the outer layer of the first trace 230 is covered with the ground wire. Adopting the foregoing method can reduce the electromagnetic interference and achieve the effect of reducing the area of the input current loop. In general, the material of the ground wire in the printed circuit board is copper foil. It should be understood that the material of the shielding material could be other preferred materials according to the frequency of the interference of the electromagnetic waves. For example, the material could be a low-resistivity metallic material or a high permeability material. More specifically, the material of the shielding material could be copper, brass, aluminum, nickel, silver, steel plate, phosphor bronze, rustless steel, nickel brass, metal coating, or conductive coating, etc.

In summary, in the display device 100 of the present embodiment, the DC-DC converter 220 is disposed near the gate driver series 400, that is, the length of the first trace is longer than the length of the second trace, so that it minimizes the path of the current voltage. Further, the trace of the connector 210 outputting a voltage to the DC-DC converter 220 is covered with the shielding material 232, so as to reduce the generation of electromagnetic interference.

Although the invention herein, with reference to several illustrative embodiments, has been described for the present invention, it should be understood to an ordinary skilled person in the art that the invention is not limited to the embodiments, but rather that various changes or modifications thereof are possible without departing from the spirit of the invention. However, the terms “a” and “an” do not mean that quantitative restrictions, but rather indicate the presence of at least one of the referenced item.

What is claimed is:

1. A display device, comprising:
a display panel having a source driver deployed in the first direction and a gate driver deployed in the second direction, and the source driver and the gate driver being used for driving the display panel;
a connector for connecting an external power source to receiving a voltage therefrom;
a DC-DC converter disposed near the gate driver and electrically connected to the source driver, the gate driver and the connector, for receiving the voltage from the connector and converting the voltage into a driving voltage to be applied to the display panel, wherein the DC-DC converter is deposed on a printed circuit board and includes a pulse width modulation circuit and a charge pump, and the pulse width modulation circuit is electrically connected to the charge pump;
a first trace for connecting the connector and the DC-DC converter, wherein the first trace is covered with a shielding material; and
a second trace for connecting the DC-DC converter and the source driver, wherein a length of the first trace is longer than a length of the second trace.

2. A display device, comprising:
a display panel having a source driver deployed in the first direction and a gate driver deployed in the second direction, and the source driver and the gate driver are used for driving the display panel;
a connector for connecting an external power source to receiving a voltage therefrom;
a DC-DC converter disposed near the gate driver and electrically connected to the source driver, the gate driver, and the connector, for receiving the voltage from the connector and converting the voltage into a driving voltage to be applied to the display panel;
a first trace for connecting the connector and the DC-DC converter; and
a second trace for connecting the DC-DC converter and the source driver, wherein a length of the first trace is longer than a length of the second trace.

3. The display device as claimed in claim 2, wherein the DC-DC converter includes a pulse width modulation circuit and a charge pump, and the pulse width modulation circuit is electrically connected to the charge pump.

4. The display device as claimed in claim 2, wherein the DC-DC converter is disposed on a printed circuit board.

5. The display device as claimed in claim 2, wherein the first trace is covered with a shielding material.

6. The display device as claimed in claim 5, wherein the shielding material is cooper foil.

7. The display device as claimed in claim 2, wherein the voltage outputted from the connector to the DC-DC converter is 12 volts.

8. A printed circuit board for a display device, the display device including a display panel which has a source driver deployed in the first direction and a gate driver deployed in the second direction, and the source driver and the gate driver being used for driving the display panel, the printed circuit board comprising;
a connector for connecting an external power source to receive a voltage therefrom;
a DC-DC converter for transmitting the voltage to the source driver and the gate driver;
a first trace for connecting the connector and the DC-DC converter; and
a second trace for connecting the DC-DC converter and the source driver, wherein a length of the first trace is longer than a length of the second trace.

9. The printed circuit board as claimed in claim 8, wherein the DC-DC converter includes a pulse width modulation circuit and a charge pump, and the pulse width modulation circuit is electrically connected to the charge pump.

10. The printed circuit board as claimed in claim 8, wherein the first trace is covered with a shielding material.

11. The printed circuit board as claimed in claim 8, wherein the shielding material is copper foil.
